(19) United States
(12) Patent Application Publication
(10) Pub. No.: US 2003/0201006 A1
(43) Pub. Date: Oct. 30, 2003

(54) Open loop alkali metal thermal to electric converter

(76) Inventors: Robert K. Sievers, Clifton Park, NY (US); David A. Butkiewicz, Pinckney, MI (US); Robert W. Fletcher, Novi, MI (US); Thomas K. Hunt, Ann Arbor, MI (US)

Correspondence Address: Ryan B. Kennedy, BRINKS HOFER GILSON & LIONE, P.O. Box 10395, Chicago, IL, 60610, US

(21) Appl. No.: 10/358,957

(22) Filed: Feb. 5, 2003

Related U.S. Application Data
(60) Provisional application No. 60/354,838, filed on Feb. 5, 2002.

(51) Int. Cl. H01L 35/02; H01L 35/30

(52) U.S. Cl. 136/205; 136/234

(57) ABSTRACT

The present invention includes an open-loop AMTEC cell operable in a delivery mode and in a priming mode. In the delivery mode, the cell provides electrical potential through electrochemical reactions, which persist until the ion content of the cell is exhausted. In the priming mode, the electrochemical potential of the cell is established through an outside electrical potential or through a reversal of the thermal gradient within the cell. The cell of the present invention is particularly operable in accordance with a preferred method and also as a component of a suitable electrical system.

### FIELD OF THE INVENTION

The present invention is directed towards an open-loop alkali metal thermal to electric converter (AMTEC) cell adapted for operation in a delivery mode and a priming mode, and a method of using the same.

### BACKGROUND AND SUMMARY OF THE INVENTION

An AMTEC cell generally comprises a closed container separated into high-pressure and low-pressure regions by a solid electrolyte. In the higher pressure region, alkali metal is in thermal contact with a heat source. In the lower pressure region, alkali metal is condensed by the removal of heat. During operation of the AMTEC cell, a heat source raises the temperature of the liquid alkali metal within the high-pressure zone to a high temperature and a correspondingly high vapor pressure which creates a vapor pressure differential across the solid electrolyte. The resulting electrochemical potential difference between the regions causes migration of the alkali metal ions into the solid electrolyte with concomitant loss of electrons. These electrons flow through the external circuit and recombine with alkali metal ions passing out of the solid electrolyte at a porous electrode, neutralizing the alkali metal ions. In this way, the cell acts as a source of electrical potential for an electrical circuit.

Typical AMTEC cells employ at least one solid electrolyte structure in the form of a beta-alumina solid electrolyte (BASE) tube of varying geometries with the high-pressure alkali metal exposed to the BASE tube inner surface, and low-pressure alkali metal exposed to the BASE tube outer surface. The BASE tube element's inner and outer surfaces are overlaid with permeable electrodes, which are connected to each other through an external load circuit. The BASE tube provides the functions of the solid electrolyte structure discussed previously. Neutral alkali metal atoms incident on the BASE tube's inner surface give up their electrons at the anode. The resulting sodium ions pass through the tube wall under the applied chemical activity gradient, and the emerging alkali metal ions are neutralized at the cathode by electrons returning from an external load.

The present state of the art AMTEC systems use either electromagnetic pumps or fine capillary structures to recirculate the alkali metal working fluid from the condenser region to the hot anode region so that the power delivery can be continuous. These subsystems add a significant cost and complexity to the converter fabrication impacting both operational issues and reliability. Since many applications do not require long term continuous operation, a new, more cost-effective approach is needed for AMTEC cells with a finite run-time for emergency use. Moreover, there is a need in the art for AMTEC cells that may be depleted and regenerated for subsequent use.

Accordingly, the present invention includes an open-loop AMTEC cell operable in a delivery mode and in a priming mode. In the delivery mode, the cell provides electrical potential through electrochemical reactions, which persist until the ion content of the cell is exhausted. Subsequent to the delivery mode, the cell may be disposed of, or it may be primed for subsequent use. In the priming mode, the electrochemical potential of the cell is established through an outside electrical potential or through a reversal of the thermal gradient within the cell. Moreover, a system of open-loop AMTEC cells may be coupled in series such that one or more cells may be in the delivery mode while simultaneously one or more different cells are in the priming mode. This approach reduces the complexity and cost of the AMTEC system, making the application of such a system more economically and technically feasible.

### BRIEF DESCRIPTION OF THE DRAWINGS

In order to appreciate the manner in which the advantages and objects of the invention are obtained, a more particular description of the invention will be rendered by reference to specific embodiments thereof which are illustrated in the appended drawings. Understanding that these drawings only depict preferred embodiments of the present invention and are not therefore to be considered limiting in scope, the invention will be described and explained with additional specificity and detail through the use of the accompanying drawings in which:

FIG. 1 is a cross-sectional perspective view of an open-loop AMTEC cell in accordance with the present invention.

FIG. 2 is a cross-sectional view of a solid electrolyte structure in accordance with the present invention.

FIG. 3 is a flow chart illustrating a method operating the AMTEC cell of the present invention.

FIG. 4 is a block diagram of an electrical power system of which the AMTEC cell of the present invention is a part.

### DETAILED DESCRIPTION OF THE INVENTION

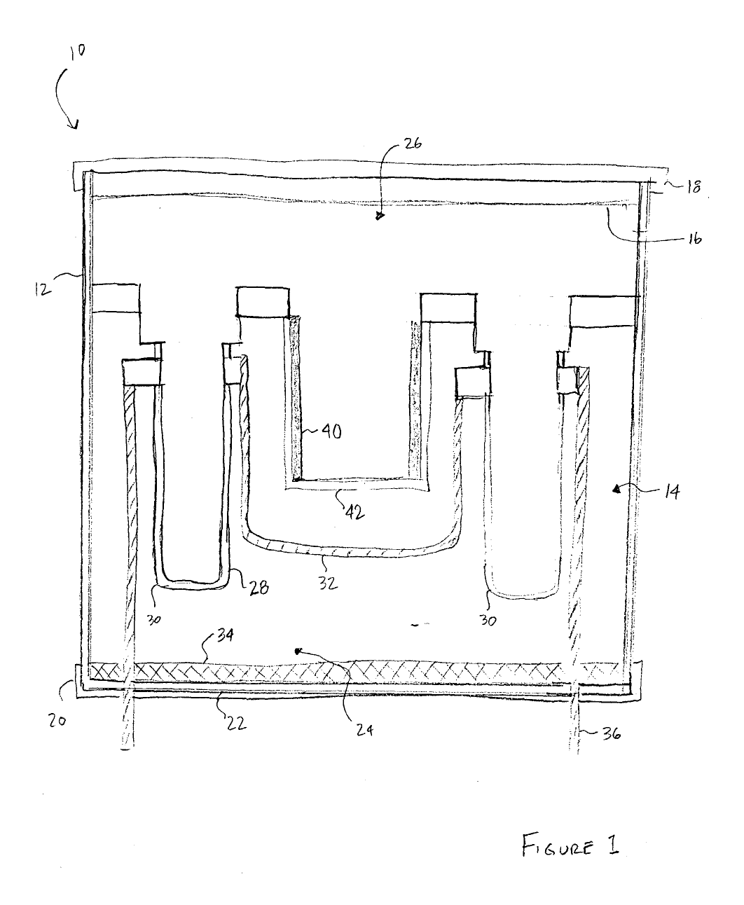

An AMTEC cell 10 incorporating the teachings of the present invention is illustrated in FIG. 1. The AMTEC cell 10 includes a cell wall 12 defining a chamber 14 which is closed at a first end 16 by a first end cap 18. The first end 16 is generally known in the art as the hot end of the cell 10. The chamber 14 is also closed at a second end 20 by a second end cap 22. The second end 20 is generally known in the art as the cold end of the cell 10.

The chamber 14 is separated into a low-pressure zone 24 and a high pressure zone 26 by a solid electrolyte structure 28. In the illustrated embodiment, the solid electrolyte structure 28 includes a plurality of beta-alumina solid electrolyte (BASE) tubes 30 electrically connected in series by an external load circuit 32. The circuit 32 is coupled to a terminal 36 projecting exterior of the cell 10 to allow power output from the cell. Although the BASE tubes 30 are shown, it is to be understood that the present invention is also suitable for use in conjunction with solid electrolyte structures of other configurations such as flat plate bi-polar stacks.

A condenser 34 is disposed in, and therefore communicates with, the low-pressure zone 24. As can be seen, the condenser 34 is coupled to the cell wall 12 about its periphery adjacent the second end cap 22. An alkali metal reservoir 42 communicates with the high-pressure zone 26. The alkali metal reservoir 42 contains a wicking structure 40 along its inner walls for ensuring that the alkali metal migrates towards the hot end 16 of the cell 10.

In a preferred operation, liquid sodium evaporates at the alkali metal reservoir 42 and the high-pressure sodium vapor is returned to the high-pressure side of the solid electrolyte structure 28 through the wicking structure 40. Neutral sodium atoms incident on the high pressure side of the electrolyte structure 28 release their electrons to an inner electrode. The resulting sodium ions pass through the solid electrolyte structure 28 under an applied pressure gradient and the emerging sodium vapor ions are neutralized at an outer electrode by electrons returning from the external load. The neutral sodium atom vapor leaving the outer electrode migrates through the low-pressure zone 24 and condenses at the condenser 34. Once the liquid sodium within the alkali metal reservoir 42 is depleted during the delivery mode, the cell 10 can be primed as discussed further herein.

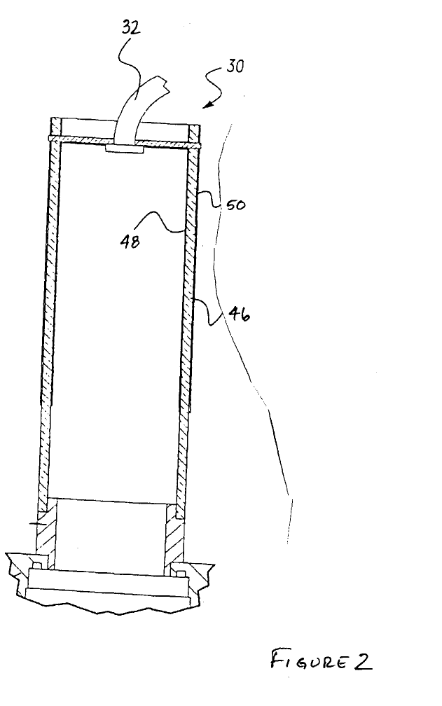

As shown in FIG. 2, each BASE tube 30 includes a wall 46, which under a suitable pressure gradient conducts sodium ions but not neutral sodium atoms. The inner surface of each BASE tube 30 is covered with a porous electrode 48, commonly the anode. Similarly, the outer surface of each BASE tube 30 is covered with a porous electrode 50, commonly the cathode. Each anode 48 is connected to the cathode 50 of an adjacent BASE tube 30 through the internal series circuit 32. As such, neutral sodium atoms incident on the inner surface of the tube 30 give up their electrons at the anode 48, enter the BASE tube walls as sodium ions and pass through the tube wall 46 under the applied pressure gradient. The emergent sodium ions are neutralized at the cathode 50 by electrons returning from the external load (not shown).

As noted, the AMTEC cell 10 of the present invention is adapted for use in a delivery mode and a priming mode. During the delivery mode, the interior of the BASE tube 30 is set at a temperature in the range of 600 to 900 degrees Celsius, while the condenser 34 surface is kept cooler, in a temperature range of 200 to 600 degrees Celsius. The resulting temperature gradient is directly related to the applied pressure gradient, which is the motive force behind the delivery phase.

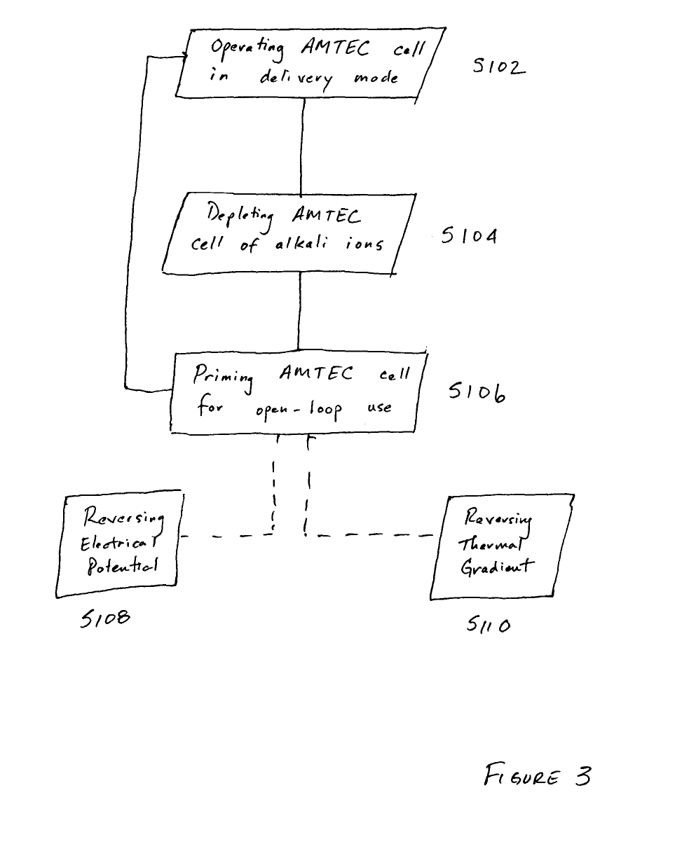

However, unlike a conventional AMTEC cell, the present invention may be primed to power another load after the alkali metal ions have been depleted. FIG. 3 is a flowchart outlining the methodology of a preferred use of the present invention. In step S102, the cell 10 is operated in a delivery mode in which the neutral sodium atoms incident on the inner surface of the tube 30 give up their electrons at the anode 48, enter the BASE tube walls as sodium ions and pass through the tube wall 46 under the applied pressure gradient. The internal series circuit 32 is coupled to a terminal 36 through which an applied voltage is used to drive an electrical load. As indicated in step S104, use of the cell 10 to power an electrical load will deplete the cell 10 of alkali ions.

In step S106, the cell 10 may be primed for further open-loop use, thus returning to step S102. The priming mode, indicated by step S106, may occur in one of two general fashions either in combination or alone. In step S108, the cell 10 is primed by reversing the electrical potential at the terminal 36 of the cell, thus pushing the recently-united electrons and ions back into the BASE tube 30 for the delivery mode. Alternatively, step S110 shows that priming may be accomplished by reversing the thermal gradient between the hot end 16 of the cell 10 and the condenser 34. A reversal of the thermal gradient may be accomplished by cooling the alkali metal reservoir 42 to a temperature below that of the condenser 34, or conversely by heating the condenser 34 to a temperature greater than that of the alkali metal reservoir 42. In order to reverse the thermal gradient, it is necessary to thermocouple the cell 10 to either a heat source for providing heat to the condenser 34 or a heat sink for drawing heat from the alkali metal reservoir 42. The process of switching the thermal gradient in the cell 10 may be hastened by applying a shorting bar across the cell terminal 36.

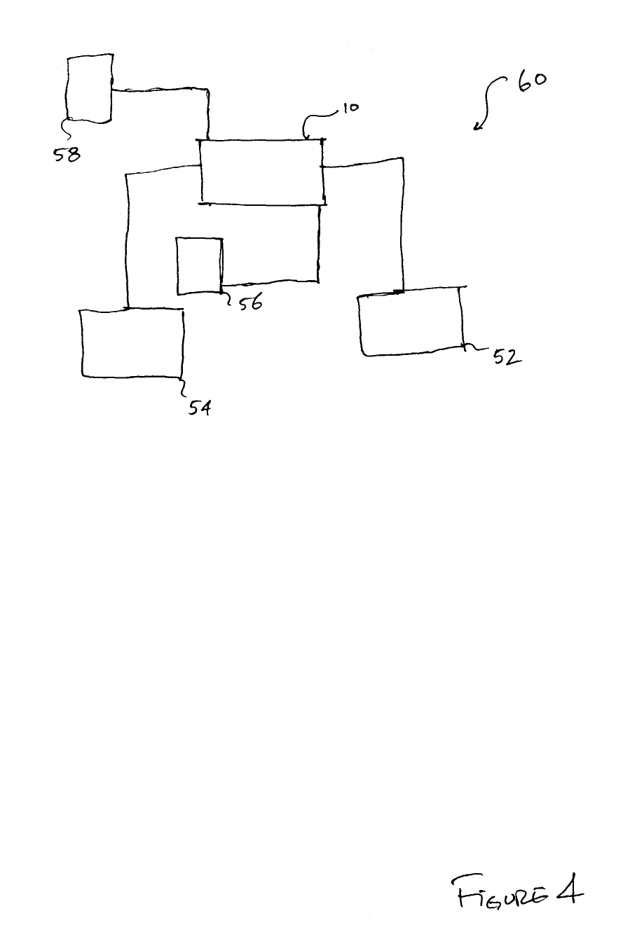

The cell 10 of the present invention is particularly well-disposed for use in an electrical system, as shown in FIG. 4. The AMTEC electrical system, designated generally as 60, includes at least one open-loop AMTEC cell as part of a delivery and priming ensemble. The cell 10 is electrically coupled to an electrical load 52, to which it provides electrical potential. A priming source 54 is also coupled to the cell 10 for providing an electrical potential to the cell 10 during the priming mode. If the potential from the priming source 54 exceeds that of the cell 10, then the alkali vapor will move into the BASE structure provided that the temperature of the condenser reservoir is above 300 degrees Celsius.

The priming source 54 could be a single AMTEC cell in the delivery mode, a group of AMTEC cells connected in series, or a commercial power outlet that provides a suitable potential. If the condenser and anode spaces in the depleted cell 10 are at or near thermal equilibrium at a temperature above 400 degrees Celsius, then it will have very low series impedance. In this state, the depleted cell 10 can be connected in series with a charged AMTEC cell as the load for which the latter is providing current.

As noted earlier, the cell 10 may be primed by reversing the thermal gradient present in the delivery mode. Accordingly, the system 60 also includes alternative configurations in which a heat source 58, a heat sink 56, or both a heat source 58 and a heat sink 56 are thermocoupled to the cell 10.

As described, the present invention includes an open-loop AMTEC cell operable in a delivery mode and in a priming mode. In the delivery mode, the cell provides electrical potential through electrochemical reactions, which persist until the ion content of the cell is exhausted. In the priming mode, the electrochemical potential of the cell is established through an outside electrical potential or through a reversal of the thermal gradient within the cell. The cell of the present invention is particularly operable in accordance with a preferred method and also as a component of a suitable electrical system.

Those skilled in the art can now appreciate from the foregoing description that the broad teachings of the present invention can be implemented in a variety of forms. Therefore, while this invention has been described with reference to particular embodiments, it is understood that these embodiments are exemplary and are not limiting, and further that the scope and breadth of the present invention is found in the following claims.

1. An open-loop alkali metal thermal to electric conversion (AMTEC) cell comprising:
a solid electrolyte structure separating the cell into a high-pressure zone and a low-pressure zone, the high-pressure zone communicating with a hot end of the cell and the low-pressure zone communicating with a cold end of the cell;
an alkali metal reservoir to contain an alkali metal, the alkali metal reservoir communicating with the hot end of the cell;
a condenser communicating with the low-pressure zone of the cell for condensing alkali metal vapor migrating through the low-pressure zone;
an electrical conductor coupled to the solid electrolyte structure and extending through the cell as a terminal for providing electrical potential to an electrical load, the electrical conductor having an anode potential and a cathode potential;
wherein the alkali metal flows from the alkali metal reservoir to the condenser through the solid electrolyte structure, and further wherein the solid electrolyte structure inhibits the flow of alkali metal from the condenser to the alkali metal reservoir.

2. The open-loop AMTEC cell of claim 1 wherein the cell is adapted for a priming mode, wherein in the priming mode, the cell is primed by providing a predetermined positive potential to the cathode potential.

3. The open-loop AMTEC cell of claim 2 wherein in the priming mode, the cell is primed by increasing the temperature within the condenser.

4. The open-loop AMTEC cell of claim 2 wherein in the priming mode, the cell is primed by decreasing the temperature within the solid electrolyte structure.

5. The open-loop AMTEC cell of claim 1 wherein the solid electrolyte structure is a beta-alumina solid electrolyte.

6. The open-loop AMTEC cell of claim 1 wherein the alkali metal is one of sodium or potassium

7. The open-loop AMTEC cell of claim 1 wherein the alkali metal is sodium.

8. The open-loop AMTEC cell of claim 1 wherein the alkali metal is potassium.

9. A method of operating a system of alkali thermal to electric conversion (AMTEC) cells comprising the steps of:
providing an AMTEC cell having a cathode potential, a condenser, and a solid electrolyte structure;
providing a predetermined amount of alkali metal within an alkali metal reservoir,
disposing the AMTEC cell in a delivery mode whereby the AMTEC cell provides electrical potential to an electrical load, thereby depleting the predetermined amount of alkali metal from the alkali metal reservoir;
disposing the AMTEC cell in a priming mode whereby the AMTEC cell is primed for subsequent delivery, thereby returning the predetermined amount of alkali metal to the alkali metal reservoir.

10. The method of claim 9 wherein the step of disposing the AMTEC cell in a priming mode includes one of providing a predetermined positive potential to the cathode potential, increasing the temperature within the condenser, or decreasing the temperature within the solid electrolyte structure.

11. The method of claim 9 wherein the step of disposing the AMTEC cell in a priming mode includes increasing the temperature within the condenser.

12. The method of claim 9 wherein the step of disposing the AMTEC cell in a priming mode includes decreasing the temperature within the solid electrolyte structure.

13. The method of claim 9 wherein the step of disposing the AMTEC cell in a priming mode includes connecting the cathode potential to a commercial power source having an electrical potential greater than the cathode potential.

14. The method of claim 9 wherein the step of disposing the AMTEC cell in a priming mode includes connecting the cathode potential to a second AMTEC cell having an electrical potential greater than the cathode potential.

15. A system for providing electrical potential alkali metal thermal to electric conversion cells comprising:
at least one AMTEC cell having a cathode potential, a condenser, and a solid electrolyte structure;
an electrical load to which the at least one AMTEC cell delivers electrical potential during a delivery mode;
a priming source to provide an electrical potential to the at least one AMTEC cell during a priming mode, the electrical potential greater than the cathode potential.

16. The system of claim 15 wherein the solid electrolyte structure is a beta-alumina solid electrolyte.

17. The system of claim 15 wherein the alkali metal is one of sodium or potassium

18. The system of claim 15 wherein the alkali metal is sodium.

19. The system of claim 15 wherein the alkali metal is potassium.

20. The system of claim 15 further comprising a heat source to increase the temperature within the condenser.

21. The system of claim 16 further comprising a heat sink to decrease the temperature within the solid electrolyte structure.
